(19) United States
(12) Patent Application Publication
(10) Pub. No.: US 2025/0067794 A1
(43) Pub. Date: Feb. 27, 2025

(54) CIRCUIT ARRANGEMENT WITH A DIAGNOSTIC FUNCTION FOR ASICS AND METHOD FOR DIAGNOSIS OF ASICS

(71) Applicant: DR. JOHANNES HEIDENHAIN GmbH, Traunreut (DE)

(72) Inventors: Elmar MAYER, Nussdorf (DE); Mitja BEH, Traunstein (DE); Martin VON BERG, Uebersee (DE); Johann OBERHAUSER, Vachendorf (DE); Ralf OCHSENBRUECHER, Grabenstaett (DE)

(21) Appl. No.: 18/813,055

(22) Filed: Aug. 23, 2024

(30) Foreign Application Priority Data
Aug. 23, 2023 (DE) 10 2023 208 060.5

(51) Int. Cl. G01R 31/28

(52) U.S. Cl. CPC G01R 31/2829

(57) ABSTRACT

A circuit arrangement with a diagnostic function, in particular for use in position-measuring devices, includes a higher-level application-specific integrated circuit (ASIC) having a diagnostic unit and an electronic circuit configured to perform a first intended function, and at least one lower-level ASIC having a parameter-measuring unit and an electronic circuit a second intended function. The parameter-measuring unit and the diagnostic unit are interconnected via a data channel. The parameter-measuring unit is configured to determine a plurality of functional parameters of the electronic circuit of the lower-level ASIC, and to transmit the functional parameters via the data channel to the diagnostic unit. The diagnostic unit is configured to establish operational readiness of the electronic circuit of the at least one lower-level ASIC by evaluating the functional parameters.

### CROSS REFERENCE TO RELATED APPLICATIONS

This application claims benefit to German Patent Application No. DE 10 2023 208 060.5, filed on Aug. 23, 2023, which is hereby incorporated by reference herein.

### FIELD

The present invention relates to a circuit arrangement with a diagnostic function for application-specific integrated circuits (ASICs), and a method for diagnosis of ASICs. The invention also relates to a position-measuring device.

### BACKGROUND

With the increasing digitization in automation technology required by Industry 4.0, the complexity of measuring devices in automation technology, such as rotary encoders and linear encoders, increases as well. In order to minimize the space requirements for the resulting extensive electronic circuits, there is a trend to integrate more and more functional modules of the electronic circuits into ASICs.

DE 10 2008 051 083 A1, for example, describes a gear-based multi-turn rotary encoder having a single-turn stage with a single-turn scanning unit for measuring the angular position of a shaft, and a plurality of multi-turn stages, each having a multi-turn scanning unit for determining the number of revolutions made by the shaft. Both the single-turn scanning unit and each multi-turn scanning unit may include an ASIC.

Another Industry 4.0 requirement is the ability of measuring devices to autonomously determine their operational readiness. For this reason, ASICs are often equipped with self-diagnostic functions. These are based on measuring functional parameters of the integrated electronic circuit and evaluating the measurement results. The result of the evaluation is then output by the individual ASICs of the circuit to a respective central location, where the operational readiness of the overall circuit is then ascertained. However, in order to implement the self-diagnostic functions of the ASICs, substantial additional circuit complexity is required, which makes these components even more complex.

### SUMMARY

In an embodiment, the present disclosure provides a circuit arrangement with a diagnostic function, in particular for use in position-measuring devices. The circuit arrangement includes a higher-level application-specific integrated circuit (ASIC) having a diagnostic unit and an electronic circuit configured to perform a first intended function, and at least one lower-level ASIC having a parameter-measuring unit and an electronic circuit configured to perform a second intended function. The parameter-measuring unit and the diagnostic unit are interconnected via a data channel. The parameter-measuring unit is configured to determine a plurality of functional parameters of the electronic circuit of the lower-level ASIC, and to transmit the functional parameters via the data channel to the diagnostic unit. The diagnostic unit is configured to establish operational readiness of the electronic circuit of the at least one lower-level ASIC by evaluating the functional parameter.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a first exemplary embodiment of an inventive circuit arrangement in connection with a multi-turn rotary encoder;

FIG. 2 shows a flow chart of a method according to the invention;

FIG. 3 shows a block diagram of a parameter-measuring unit according to the invention;

FIG. 4 shows a block diagram of a diagnostic unit according to the invention;

FIG. 5 shows a second exemplary embodiment of an inventive circuit arrangement in connection with a multi-turn rotary encoder; and

FIG. 6 shows a third exemplary embodiment of an inventive circuit arrangement in connection with a single-turn rotary encoder with additional sensors.

### DETAILED DESCRIPTION

In an embodiment, the present invention provides an improved circuit arrangement for establishing the operational readiness of a circuit having a plurality of ASICs, in particular by a circuit arrangement with a diagnostic function, particularly for use in position-measuring devices.

The circuit arrangement includes a higher-level ASIC having an electronic circuit for performing an intended function and at least one lower-level ASIC having an electronic circuit for performing an intended function, the at least one lower-level ASIC including a parameter-measuring unit, and the higher-level ASIC including a diagnostic unit, which units are interconnected via a data channel, and the parameter-measuring unit being configured to determine a plurality of functional parameters of the electronic circuit of the lower-level ASIC, and to transmit the same via the data channel to the diagnostic unit, and the diagnostic unit being configured to establish the operational readiness of the electronic circuit of the respective lower-level ASIC by evaluating the functional parameters.

In another embodiment, the present invention provides an improved method for establishing the operational readiness of a circuit having a plurality of ASICs, in particular by a method for operating a circuit arrangement with a diagnostic function, particularly for use in position-measuring devices.

The circuit arrangement forming the basis of the method includes a higher-level ASIC having an electronic circuit for performing an intended function and at least one lower-level ASIC having an electronic circuit for performing an intended function, the at least one lower-level ASIC including a parameter-measuring unit, and the higher-level ASIC including a diagnostic unit, which units are interconnected via a data channel. In accordance with the proposed method, the parameter-measuring unit determines a plurality of functional parameters of the electronic circuit of the lower-level ASIC and transmits the same via the data channel to the diagnostic unit, and the diagnostic unit establishes the operational readiness of the electronic circuit of the respective lower-level ASIC by evaluating the functional parameters.

In a further embodiment, the present invention provides a position-measuring device having an improved capability for establishing operational readiness.

Further advantages of embodiments of the present invention will be apparent from the following description of exemplary embodiments.

In the following description of advantageous embodiments, the same numeration identifying components earlier described with reference to a figure is retained in the figures to follow. Dashed lines indicate advantageous variants of an embodiment, to which reference is made in the description.

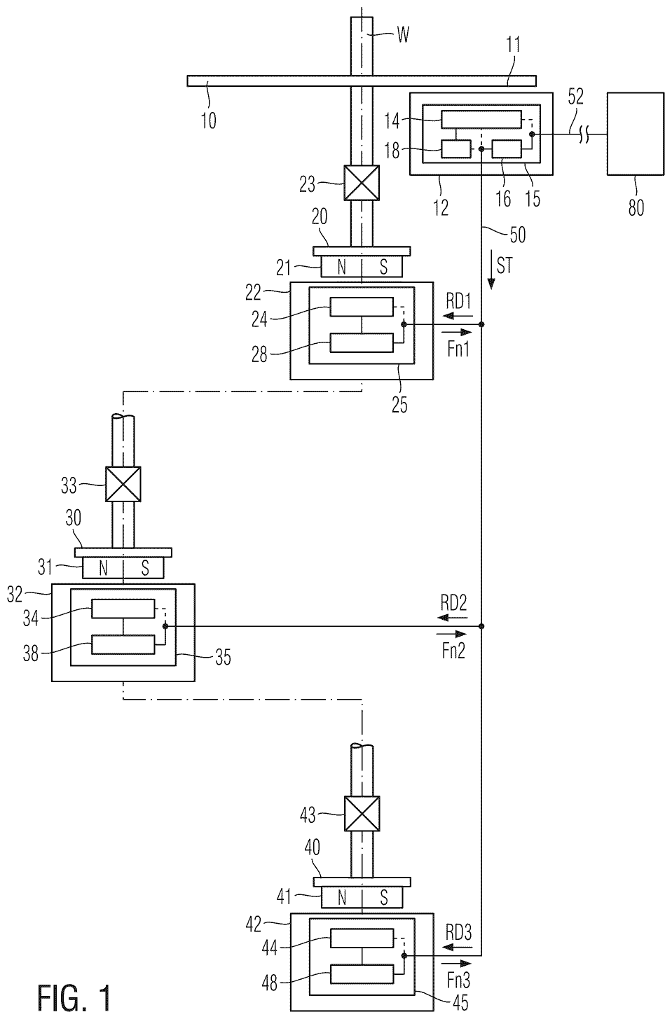

FIG. 1 shows a first exemplary embodiment of an inventive circuit arrangement in connection with a multi-turn rotary encoder. The multi-turn rotary encoder essentially includes a single-turn measurement assembly for measuring a position value indicative of the angular position of a shaft W, and a multi-turn measurement assembly for counting the revolutions made by shaft W.

The single-turn measurement assembly is composed of a single-turn code disk 10 whose center M is non-rotatably connected to the shaft to be measured, and which carries an annular code track 11 disposed concentrically with respect to center M. Furthermore, a single-turn position sensor 12 is provided for reading code track 11 and for determining the absolute position value corresponding to the angular position of single-turn code disk 10. If an optical scanning principle is used for position determination, code track 11 is made up of, for example, a line pattern having regions with different optical properties, e.g., transparent/non-transparent or reflective/non-reflective. Light is emitted from a light source toward code track 11, modulated by it, and finally strikes photodetectors, which are advantageously disposed in single-turn position sensor 12. For the sake of clarity, no light source is shown here. Code track 11 may be encoded for absolute measurement and/or for incremental measurement, and in some instances may include a plurality of graduation tracks arranged side-by-side.

As an alternative to the optical scanning principle, an inductive, magnetic or capacitive scanning principle may also be used.

The multi-turn measurement assembly is used to measure rotational data that is suitable for determining the number of revolutions made by shaft W. In the example shown, it includes three multi-turn stages. Each of these multi-turn stages includes a multi-turn code disk 20, 30, 40 having a respective code element 21, 31, 41, as well as a multi-turn position sensor 22, 32, 42 for measuring the angular position of code elements 21, 31, 41. Multi-turn code disks 20, 30, 40 are driven by the shaft W to be measured via a three-stage reduction gear 23, 33, 43. During rotation of shaft W, first multi-turn code disk 20, which is driven by first gear stage 23, has the highest rotational speed, and third multi-turn code disk 40, which is driven by the third and at the same time last gear stage 43, has the lowest rotational speed. The speed reduction ratio of gear stages 23, 33, 43 is, for example, 16:1, which means that the input shaft of the respective gear stage 23, 33, 43 will turn 16 times for every one rotation of the output shaft.

The multi-turn stages are frequently implemented using a magnetic scanning principle. In this case, code elements 21, 31, 41 are made up of disk-shaped permanent magnets which are firmly connected to multi-turn code disks 20, 30, 40 such that the magnets will rotate together with the multi-turn code disks 20, 30, 40, and which each have a dipole, i.e., a magnetic north pole N and south pole S. To determine the angular position of code elements 21, 31, 41, the dipoles are scanned by magnetic sensors (e.g., Hall effect sensors, MR sensors) disposed in the respective multi-turn position sensors 22, 32, 42. The resolution of multi-turn position sensors 22, 32, 42 is, for example, 8 bits, which means that one revolution of multi-turn code disks 20, 30, 40 is resolved with 256 absolute position values and made available in the form of data words. By combining the data words, it is possible to determine the number of revolutions made by shaft W.

As an alternative to the magnetic scanning principle, an inductive, optical, or capacitive scanning principle may also be used.

In single-turn position sensor 12, the position values of the single-turn measurement assembly and the data words of the multi-turn stages are combined into one overall position value that includes both the angular position of shaft W and the number of revolutions made by shaft W.

In addition, single-turn position sensor 12 is configured for communication with subsequent electronics 80 via an external data channel 52. The communication includes, for example, outputting the overall position value to subsequent electronics 80.

A component of single-turn position sensor 12 is an application-specific integrated circuit (ASIC) in which an electronic circuit 14 including a plurality of essential functional blocks of the single-turn position sensor 12 is integrated. Examples to be mentioned include photodetectors, evaluation electronics, an output interface, an internal interface, as well as a combining unit. Electronic circuit 14 is used to perform the intended functions of the ASIC. In the context of this exemplary embodiment, this ASIC is referred to as higher-level ASIC 15.

In this exemplary embodiment, the intended functions of higher-level ASIC 15 include:
determining absolute position values,
determining the overall position value, and
communicating with subsequent electronics 80.

Each multi-turn position sensor 22, 32, 42 is also essentially composed of an ASIC in which an electronic circuit 24, 34, 44 including a plurality of essential functional blocks of the respective multi-turn position sensor 22, 32, 42 is integrated. In this example, these may be the magnetic sensors, evaluation electronics, and an output interface. This electronic circuit 24, 34, 44 is used to perform the intended functions of the ASIC. In the context of this exemplary embodiment, these ASICs are referred to as lower-level ASICs 25, 35, 45.

In this exemplary embodiment, one intended function of the lower-level ASICs 25, 35, 45 is to determine the data words that indicate the absolute angular position of the respective multi-turn code disks 20, 30, 40.

Higher-level ASIC 15 is connected to lower-level ASICs 25, 35, 45 for purposes of communication via at least one data channel 50. Any interface connection permitting bidirectional transmission of digital data may be used as the data channel 50. Both point-to-point and bus interfaces are suitable. Serial or parallel data transmission can be used. In a preferred embodiment, data channel 50 is provided by a bidirectional serial interface, in particular an I2C interface.

In accordance with the invention, higher-level ASIC 15 has a diagnostic unit 16, and each lower-level ASIC 25, 35, 45 has a parameter-measuring unit 28, 38, 48. Diagnostic unit 16 is configured for communication with parameter-measuring units 28, 38, 48 via data channel 50.

Advantageously, the communication between electronic circuit 14 of higher-level ASIC 15 and electronic circuit 24, 34, 44 of lower-level ASICs 25, 35, 45 also takes place via data channel 50, so that only one interface connection must be provided for the entire communication between higher-level ASIC 15 and lower-level ASICs 25, 35, 45.

Each parameter-measuring unit 28, 38, 48 is suitably configured to determine, in particular by measurement, a plurality of functional parameters Fn1, Fn2, Fn3 of the respective lower-level ASIC 25, 35, 45. In this connection, functional parameters are parameters that allow conclusions to be drawn about the proper functioning of electronic circuit 24, 34, 44 of lower-level ASIC 25, 35, 45, such as
voltage values at defined measurement points of electronic circuit 24, 34, 44 of lower-level ASIC 25, 35, 45,
the current drawn by subcircuits or/and by the entire electronic circuit 24, 34, 44 of lower-level ASIC 25, 35, 45,
resistance values,
characteristics of digital signals, such as edge spacings, frequency, duty cycle, jitter, etc.,
processing times of subcircuits of electronic circuit 24, 34, 44 of lower-level ASIC 25, 35, 45.

For purposes of determining functional parameters Fn1, Fn2, Fn3, parameter-measuring unit 28, 38, 48 includes suitable measurement means, for example A/D converters, timers (in particular counters), comparators. Furthermore, parameter-measuring unit 28, 38, 48 may include signal generators, for example, current and/or voltage sources, clock generators, D/A converters. Parameter-measuring unit 28, 38, 48 may also include switching means to connect the measurement means and/or the signal generators to nodes of electronic circuit 24, 34, 44 of lower-level ASIC 25, 35, 45. The measurement means, signal generators, and switching means may be associated exclusively with parameter-measuring unit 28, 38, 48, or may at least partially be associated with parameter-measuring unit 28, 38, 48 only for the purpose of performing the self-test function and may otherwise be used to perform the intended function of lower-level ASICs 25, 35, 45. In the latter case, these are subcircuits of electronic circuit 24, 34, 44.

Advantageously, the determination of functional parameters Fn1, Fn2, Fn3 is started upon receipt of a start self-test command ST, which arrives at lower-level ASICs 25, 35, 45 via data channel 50.

The determined functional parameters Fn1, Fn2, Fn3 can be transmitted to higher-level ASIC 15 via data channel 50. Advantageously, the transmission does not occur immediately after the determination is completed. Rather, a memory is provided in parameter-measuring units 28, 38, 48, in which memory functional parameters Fn1, Fn2, Fn3 can be stored. The transmission then occurs in response to the receipt of a data request command RD1, RD2, RD3, which is sent from higher-level ASIC 15 via the data channel to the respective lower-level ASIC 25, 35, 45.

In the simplest case, the point in time from which the determined functional parameters Fn1, Fn2, Fn3 are available in the respective lower-level ASIC 25, 35, 45 can be determined by waiting for a defined period of time. Alternatively, special commands may be provided by which higher-level ASIC 15 can request the status of the determination of functional parameters Fn1, Fn2, Fn3 from lower-level ASICs 25, 35, 45 via data channel 50 (polling). As a further alternative, provision may be made for lower-level ASICs 25, 35, 45 to indicate the availability of functional parameters Fn1, Fn2, Fn3 by sending a completion message via data channel 50.

In higher-level ASIC 15, functional parameters Fn1, Fn2, Fn3 can be fed to diagnostic unit 16, which is suitably configured to assess the operational readiness of the respective lower-level ASIC 25, 35, 45 by evaluating functional parameters Fn1, Fn2, Fn3. The evaluation may include checking whether individual functional parameters, or/and interdependent functional parameters are within predetermined threshold values. If the evaluation shows that all of the lower-level ASICs 25, 35, 45 are ready for operation, the system switches to a normal operation mode, otherwise it switches to a malfunction mode.

Higher-level ASIC 15 may also include a parameter-measuring unit 18. Parameter-measuring unit 18 is used to determine internal functional parameters of higher-level ASIC 15, which are evaluated in a diagnostic unit in a manner equivalent to functional parameters Fn1, Fn2, Fn3 of lower-level ASICs 25, 35, 45. In this case, higher-level ASIC 15 has a self-diagnostic function. The diagnostic unit may be the diagnostic unit 16 in which functional parameters Fn1, Fn2, Fn3 of lower-level ASICs 25, 35, 45 are evaluated as well. However, higher-level ASIC 15 may also include an additional diagnostic unit for this purpose.

The result of the evaluation of functional parameters Fn1, Fn2, Fn3 of lower-level ASICs 25, 35, 45 and, possibly, of higher-level ASIC 15 is stored in a status information STAT. Status information STAT can be output via external data channel 52 to subsequent electronics 80, thus permitting indication of the operational readiness of the multi-turn rotary encoder.

Subsequent electronics 80 takes the form of an external, independent device that is spatially separated from the multi-turn rotary encoder of this exemplary embodiment. For example, it takes the form of a numerical control system for machine tools or another controller used in automation technology. Subsequent electronics 80 is not part of the present invention.

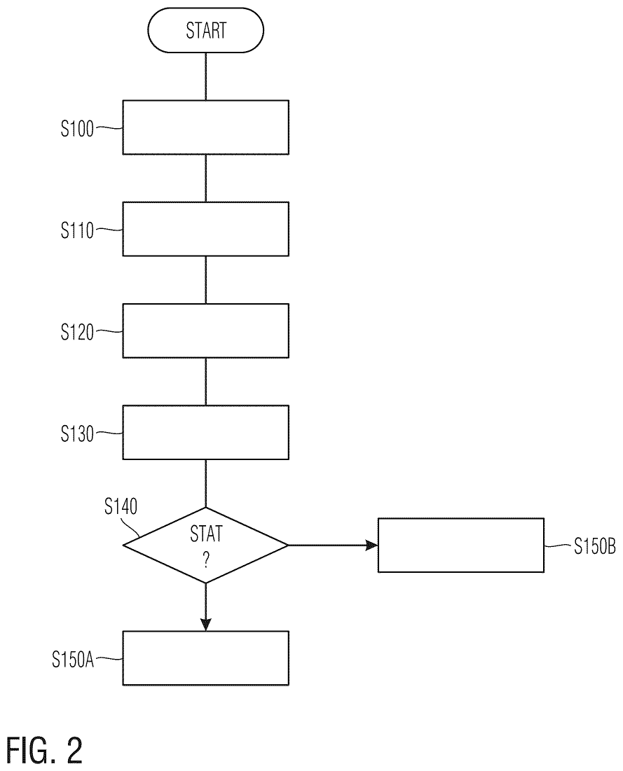

FIG. 2 shows a flow chart of a method according to the invention. The method can be performed at any time during the operation of the multi-turn rotary encoder. Advantageously, it is performed immediately after the device is turned on in order to establish operational readiness. If necessary, ASICs 15, 25, 35, 45 are initialized prior to starting the method.

In a step S100, higher-level ASIC 15 sends a start self-test command ST to at least one lower-level ASIC 25, 35, 45. Depending on the test strategy, it may be advantageous to send start self-test command ST to only one of lower-level ASICs 25, 35, 45, namely when the intention is to specifically establish the operational readiness of this particular one of lower-level ASICs 25, 35, 45. Preferably, however, start self-test command ST is sent to all lower-level ASICs 25, 35, 45 configured in accordance with the invention, so that the operational readiness of all lower-level ASICs 25, 35, 45 can be established virtually simultaneously.

In a step S110, the lower-level ASICs 25, 35, 45 that have received start self-test command ST determine the plurality of functional parameters Fn1, Fn2, Fn3 required to establish operational readiness. Higher-level ASIC 15 waits until the determination of functional parameters Fn1, Fn2, Fn3 is completed. As described above, this may be done by waiting for a defined period of time, by querying the status of the determination of functional parameters Fn1, Fn2, Fn3, or by waiting for the arrival of a completion message from lower-level ASICs 25, 35, 45.

In a step S120, functional parameters Fn1, Fn2, Fn3 are transmitted via data channel 50 to higher-level ASIC 15, in particular to diagnostic unit 16. The transmission may be started by sending data request commands RD1, RD2, RD3 to the respective lower-levels ASICs 25, 35, 45.

In a step S130, functional parameters Fn1, Fn2, Fn3 are evaluated, and the operational readiness of the respective lower-level ASIC 25, 35, 45 is assessed by diagnostic unit 16. The result of the evaluation is stored in a status information STAT.

In a step S140, based on status information STAT, a decision is made as to whether the system can switch to a normal operation mode (step S150A) or whether to switch to a malfunction mode (step S150B).

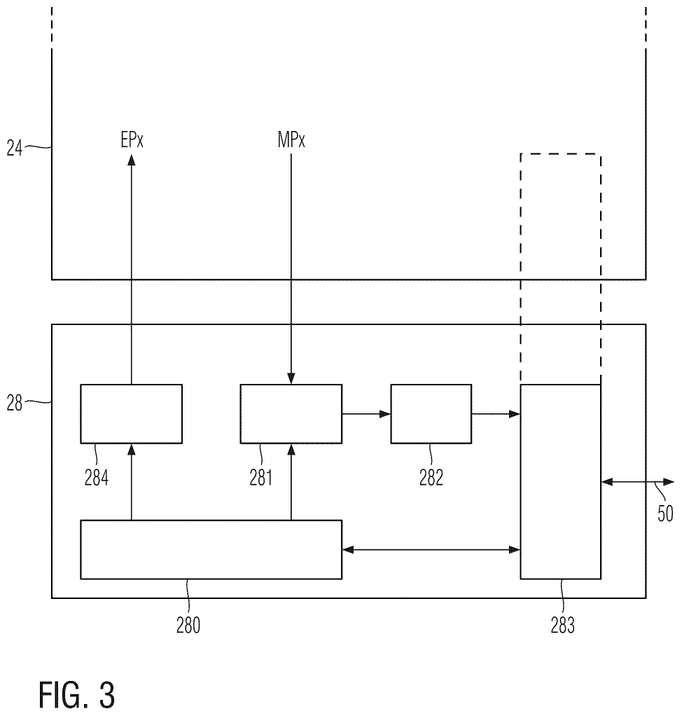

FIG. 3 shows a block diagram of a parameter-measuring unit according to the invention. The inventive parameter-measuring unit will be described with reference to parameter measuring unit 28 of FIG. 1, but parameter-measuring units 28, 38, 48 are advantageously configured identically.

Parameter-measuring unit 28 includes a sequence controller 280, measurement means 281, a memory 282, and an interface unit 283. In addition, it may include at least one signal generator 284.

Sequence controller 280 controls the sequence of the self-test function and is advantageously configured as a digital finite state machine. Sequence controller 280 controls measurement means 281, signal generator 284, and optionally memory 282 according to the commands supplied thereto from higher-level ASIC 15 via signal channel 50 and interface unit 283. Moreover, sequence controller 280 is suitably configured to indicate the completion of the self-test function or the provision of functional parameters Fn1 to higher-level ASIC 15 via interface unit 283 and data channel 50.

Measurement means 281 are used to measure functional parameters Fn1. For this purpose, they are connected to at least one measurement point MPx of electronic circuit 24 of lower-level ASIC 25. Measurement means 281 may include an A/D converter, a time measurement unit, or a comparator for carrying out the measurements. Furthermore, measurement means 281 may include switching elements to connect a plurality of measurement points MPx to the units performing the measurements for the duration of the measurement.

Functional parameters Fn1 measured by measurement means 281 can be stored in memory 282 and transmitted from interface unit 283 via data channel 50 to higher-level ASIC 15.

Signal generator 284 is suitably configured to generate at least one electrical signal and feed it to at least one feed point EPx of electronic circuit 24 of lower-level ASIC 25. Signal generators 284 may include signal-generating units such as voltage sources, D/A converters, and clock generators. Examples of electrical signals include constant voltages and/or currents, alternating voltages of any waveform, such as sinusoidal voltages, square-wave voltages . . . , etc. Signal generator 284 may also have switching elements provided therein to connect a plurality of feed points EPx to the unit within signal generator 284 that generates a signal to be fed in, in each case for the duration of the measurement of a functional parameter Fn1.

Interface unit 283 serves to allow parameter measuring unit 28 to communicate with higher-level ASIC 15 via data channel 50. The communication is bidirectional, which allows reception of commands and/or data from higher-level ASIC 15 and transmission of data, in particular functional parameters Fn1, to higher-level ASIC 15.

As indicated by the dashed line, it is particularly advantageous if the communication between electronic circuit 24 of lower-level ASIC 25 and electronic circuit 14 of higher-level ASIC 15 also takes place via interface unit 283. In this way, only a single interface connection between lower-level ASIC 25 and higher-level ASIC 15 is needed for the self-test operation and the normal intended operation of the ASICs.

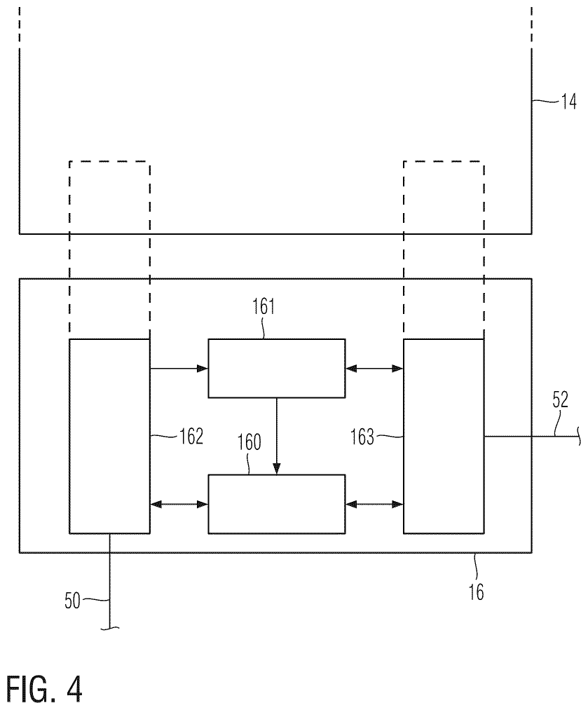

FIG. 4 shows a block diagram of a diagnostic unit 16 according to the invention. Diagnostic unit 16 includes a diagnostic controller 160, an interface unit 162, as well as a device interface 163. Furthermore, diagnostic unit 16 may include a memory 161.

Diagnostic controller 160 controls the sequence of the self-test function. To this end, it starts the determination of functional parameters Fn1, Fn2, Fn3 in parameter-measuring units 28, 38, 48 of lower-level ASICs 25, 35, 45 by sending start self-test command ST and initiates the transmission of functional parameters Fn1, Fn2, Fn3 by sending data request commands RD1, RD2, RD3. The transmission of both the commands and the data takes place via interface unit 162, data channel 50, and the interface unit 283 of the parameter-measuring unit 28, 38, 48 to be addressed.

Diagnostic controller 160 is suitably configured to check whether functional parameters Fn1, Fn2, Fn3 arriving from lower-level ASICs 25, 35, 45 are within threshold values, and to thereby assess the operational readiness of lower-level ASICs 25, 35, 45, and to decide whether to switch to normal operation mode or to malfunction mode. The threshold values may include upper and/or lower limits of individual functional parameters, and also dependencies between two or more of the functional parameters. Examples of dependencies include the ratio of input signals to output signals of amplifier circuits, or the dependence of the instantaneous values of signals that are phase-shifted with respect to each other, in particular of sinusoidal sensor signals that are phase-shifted 90° with respect to each other, such as are frequently encountered in position measurement technology.

The result of the test may be stored in a status information STAT and output to subsequent electronics 80 via device interface 163 and external data channel 52.

As indicated by the dashed lines and described above with reference to interface unit 283 of lower-level ASIC 25, it is particularly advantageous if the communication between electronic circuit 14 of higher-level ASIC 15 and electronic circuit 24, 34, 44 of the respective lower-level ASIC 25, 35, 45 also takes place via interface unit 162.

It is also advantageous if device interface 163 is suitably configured to handle not only the communication of diagnostic unit 16, but also the communication of electronic circuit 14 of higher-level ASIC 15 with subsequent electronics 80.

Memory 161 may be used to store functional parameters Fn1, Fn2, Fn3 before they are evaluated by diagnostic controller 160. In addition, it may be provided that functional parameters Fn1, Fn2, Fn3 can be transmitted from memory 161 to subsequent electronics 80, so that a fault condition can be further analyzed there.

In a further advantageous embodiment, it may be provided that the threshold values and optionally further rules for the evaluation of functional parameters Fn1, Fn2, Fn3 in diagnostic controller 160 can be stored in memory 161. If, moreover, memory 161 is writable, diagnostic unit 16 can be adapted to different lower-level ASICs, and the self-test can be performed.

As a further advantageous functionality, it may be provided that the memory 282 of the lower-level ASICs can be written to and/or erased by diagnostic unit 16 via data channel 50. This makes it possible to check the functioning of memory 282.

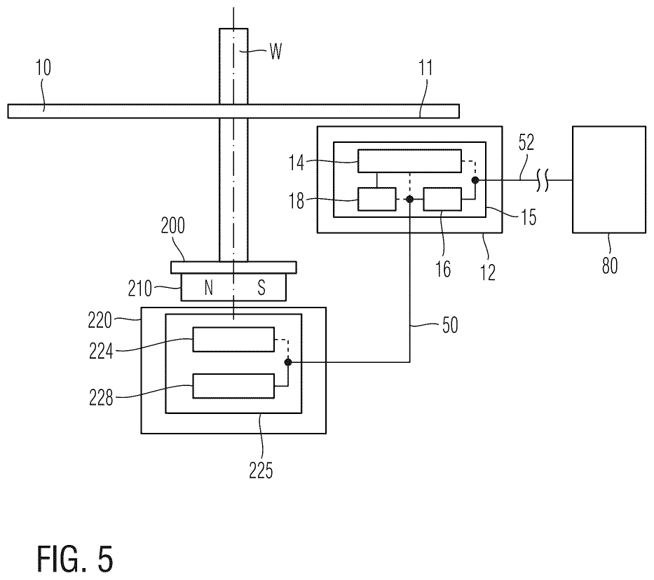

FIG. 5 shows a second exemplary embodiment of an inventive circuit arrangement in connection with a multi-turn rotary encoder. In contrast to the first exemplary embodiment, the multi-turn measurement assembly of the multi-turn rotary encoder does not have a gear-based revolution counter, but an electronic revolution counter.

The single-turn measurement assembly corresponds to that of FIG. 1, it being noted that electronic circuit 14 of higher-level ASIC 15 may differ from that of FIG. 1.

The multi-turn measurement assembly includes a multi-turn code disk 200 having a code element 210, as well as a multi-turn position sensor 220 for measuring the number of revolutions made by shaft W by measuring and evaluating the angular position of code element 210, which is non-rotatably connected to shaft W. Thus, the measuring principle is equivalent to that of a multi-turn stage of the multi-turn rotary encoder from FIG. 1.

Multi-turn position sensor 220 is essentially composed of an ASIC 225 in which an electronic circuit 224 is integrated, which is used to perform the intended functions, in particular determining the number of revolutions made by shaft W (rotational data), and transmitting the same via data channel 50 to the single-turn position sensor 12 of the ASIC 15. The ASIC 225 is thus a lower-level ASIC according to an embodiment of the invention.

In order to be able to measure the number of revolutions even when the multi-turn rotary encoder is in the turned-off state, a battery may be provided in multi-turn position sensor 220 to supply current at least to those parts of electronic circuit 224 which are required for counting revolutions. As an alternative to using a battery, multi-turn position sensor 220 may be designed according to the principle of energy harvesting, for example using a Wiegand wire.

Lower-level ASIC 225 has a parameter-measuring unit 228 that is suitably configured to determine a plurality of functional parameters Fn4 and transmit the same via data channel 50 to diagnostic unit 16 in higher-level ASIC 15. For this purpose, parameter-measuring unit 228 may be configured analogously to the parameter-measuring unit described with reference to FIG. 3.

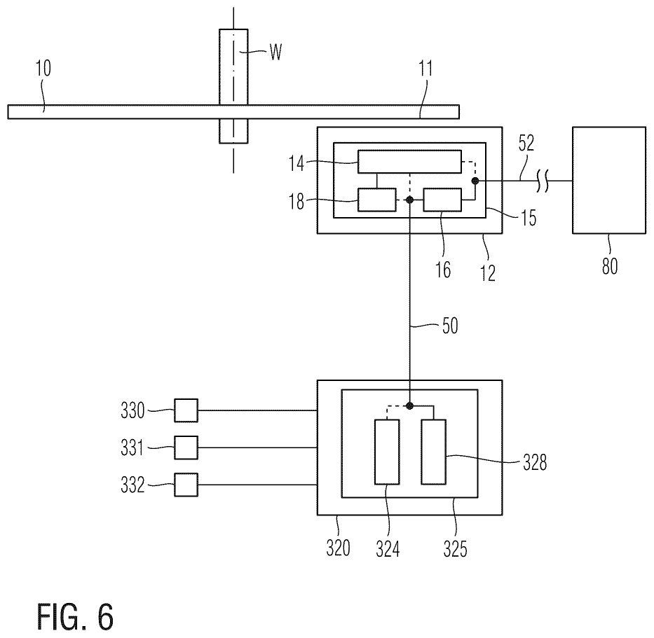

FIG. 6 shows a third exemplary embodiment of an inventive circuit arrangement in connection with a single-turn rotary encoder with additional sensors. Additional sensors are used when the intention is for a measuring device to measure additional parameters inside and/or outside of the measuring device, in addition to the primary measurement task, such as, in automation technology, measurement of the angular position of a shaft W and/or the number of revolutions made by it, or measurement of linear movements of a machine part. Prominent examples of such parameters include temperature, accelerations, vibrations, and air humidity.

The single-turn measurement assembly corresponds to that of FIG. 1, it being noted that electronic circuit 14 of higher-level ASIC 15 may differ from that of FIG. 1 because it differs in terms of the intended functions thereof.

For purposes of acquiring measurement values, there is provided a sensor data capturer 320, to which can be connected at least one, but advantageously a plurality of additional sensors 330, 331, 332.

Sensor data capturer 320 is essentially composed of an ASIC 325 in which an electronic circuit 324 is integrated, which is used to perform the intended functions, in particular querying and processing of measurement data of additional sensors 330, 331, 332, and transmitting the same via data channel 50 to the single-turn position sensor 12 of the ASIC 15. The ASIC 325 is thus a lower-level ASIC according to an embodiment of the invention.

Lower-level ASIC 325 also has a parameter-measuring unit 328 that is suitably configured to determine a plurality of functional parameters Fn5 and transmit the same via the data channel 50 to diagnostic unit 16 in higher-level ASIC 15. For this purpose, parameter-measuring unit 328 may be configured analogously to the parameter-measuring unit 28 described with reference to FIG. 3.

It should be noted that the exemplary embodiments described with reference to FIGS. 1 and 5 may also be complemented with a sensor data capturer 320. This means that the present invention is also suitable for circuit arrangements that include a plurality of different lower-level ASICS.

Therefore, it is particularly advantageous if higher-level ASIC 15, in particular its electronic circuit 14, is designed to be usable in various variants of the device and in connection with different lower-level ASICs, for example in the exemplary embodiments of FIGS. 1, 5 and 6, and in combinations thereof.

Of course, the present invention is not limited to the exemplary embodiments described herein, but rather may be suitably modified by those skilled in the art within the scope of the claims.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. A circuit arrangement with a diagnostic function for use in position-measuring devices, the circuit arrangement comprising:
a higher-level application-specific integrated circuit (ASIC) having a diagnostic unit and an electronic circuit configured to perform a first intended function; and
at least one lower-level ASIC having a parameter-measuring unit and an electronic circuit a second intended function,
wherein the parameter-measuring unit and the diagnostic unit are interconnected via a data channel,
wherein the parameter-measuring unit is configured to determine a plurality of functional parameters of the electronic circuit of the lower-level ASIC, and to transmit the functional parameters via the data channel to the diagnostic unit, and
wherein the diagnostic unit is configured to establish operational readiness of the electronic circuit of the at least one lower-level ASIC by evaluating the functional parameters.

2. The circuit arrangement as recited in claim 1, wherein the parameter-measuring unit includes a sequence controller configured to control a sequence of a self-test function, measurement means configured to determine the functional parameters through measurement at at least one measurement point of the electronic circuit, and an interface unit configured to communicate with the higher-level ASIC via the data channel.

3. The circuit arrangement as recited in claim 1, wherein the parameter-measuring unit includes a memory configured to store the functional parameters.

4. The circuit arrangement as recited in claim 3, wherein the memory is configured to be written to and/or erased by the diagnostic unit.

5. The circuit arrangement as recited in claim 1, wherein the parameter-measuring unit includes at least one signal generator configured to generate at least one electrical signal and feed the at least one electrical signal to at least one feed point of the electronic circuit.

6. The circuit arrangement as recited in claim 1, wherein the diagnostic unit includes a diagnostic controller configured to control the sequence of the self-test function, an interface unit configured to communicate with the parameter-measuring unit via the data channel, and a device interface configured to communicate with subsequent electronics via an external data channel.

7. The circuit arrangement as recited in claim 1, wherein the diagnostic unit includes a memory configured to store the functional parameters and/or threshold values for the evaluation of the functional parameters and/or further rules for the evaluation of the functional parameters.

8. A method for operating a circuit arrangement with a diagnostic function for use in position-measuring devices, the method comprising:
providing a higher-level application-specific integrated circuit (ASIC) having a diagnostic unit and an electronic circuit configured to perform a first intended function;
providing at least one lower-level ASIC having a parameter-measuring unit and an electronic circuit configured to perform a second intended function, wherein the parameter-measuring unit and the diagnostic unit are interconnected via a data channel;
by the parameter-measuring unit, determining a plurality of functional parameters of the electronic circuit of the lower-level ASIC and transmitting the functional parameters via the data channel to the diagnostic unit; and
by the diagnostic unit, establishing operational readiness of the electronic circuit of the at least one lower-level ASIC by evaluating the functional parameters.

9. The method as recited in claim 8, wherein the parameter-measuring unit includes a sequence controller, measurement means, and an interface unit, the method further comprising:
the sequence controller controlling a sequence of the self-test function,
the measurement means determining the functional parameters through measurement at at least one measurement point of the electronic circuit, and
communication being performed through the interface unit with the higher-level ASIC via the data channel.

10. The method as recited in claim 8, wherein the parameter-measuring unit includes a memory in which the functional parameters are stored.

11. The method as recited in claim 10, wherein the memory is written to and/or erased by the diagnostic unit.

12. The method as recited in claim 8, wherein the parameter-measuring unit includes at least one signal generator that generates at least one electrical signal and feeds it to at least one feed point of the electronic circuit.

13. The method as recited in claim 8, wherein the diagnostic unit includes a diagnostic controller, an interface unit, and a device interface, the method further comprising:
the diagnostic controller controlling a sequence of a self-test function,
communication being performed through the interface unit with the parameter-measuring unit via the data channel, and
communication being performed through the device interface with subsequent electronics via an external data channel.

14. The method as recited in claim 8, wherein the diagnostic unit includes a memory in which are stored the functional parameters and/or threshold values for the evaluation of the functional parameters and/or further rules for the evaluation of the functional parameters.

15. A position-measuring device comprising the circuit arrangement according to claim 1.
